(19) United States
(12) Patent Application Publication
(10) Pub. No.: US 2005/0131845 A1
(43) Pub. Date: Jun. 16, 2005

(54) Method for maintaining a technical facility technical field

(76) Inventor: Mourad Boulouednine, Munchen (DE)

Correspondence Address: OSRAM SYLVANIA INC, 100 ENDICOTT STREET, DANVERS, MA, 01923, US

(21) Appl. No.: 10/970,004

(22) Filed: Oct. 22, 2004

(30) Foreign Application Priority Data
Oct. 28, 2003 (EP) 03024906.4

(51) Int. Cl. G06F 11/00; G01R 11/56; G06G 7/62; G06F 17/50

(52) U.S. Cl. 705/412; 705/400; 703/13; 703/18; 703/1

(57) ABSTRACT

It is proposed to identify the component parts of a technical facility in an initialization phase and to record specific data of these component parts with the aid of a databank system. In a prognosis phase, the servicing intervals for the component parts of the technical facility are then calculated on the basis of the specific data of these component parts. Optionally, this is then followed by an analysis phase and an optimization phase. This allows the availability, cost-effectiveness and technically up-to-date state of the technical facility to be improved.

### TECHNICAL FIELD

The invention relates to a method for maintaining technical facilities, in particular lighting systems, i.e. facilities which comprise luminaires, lamps and possibly, in addition, ballasts for the operation of the lamps.

### BACKGROUND ART

On account of the complexity and to reduce costs, recently the documentation and maintenance of highly ramified technical facilities in buildings, for example air-conditioning systems, have increasingly been supported by special computer programs, Computer Aided Facility Management (CAFM).

### DISCLOSURE OF THE INVENTION

The object of the present invention is to provide an improved method for maintaining technical facilities, in particular lighting systems.

This object is achieved by a method for maintaining a technical facility, in particular a lighting system, with the aid of a computer system and the following method steps,

in an initialization phase:

identification of the component parts of the technical facility,
recording of specific data of the component parts with the aid of a databank system connected at least periodically to the computer system,
storage of the specific data assigned to the component parts in the computer system,
   in a prognosis phase:
calculation of servicing intervals for the component parts of the technical facility on the basis of the specific data of these component parts.

Particularly advantageous refinements can be found in the dependent claims.

The aim in particular is to improve the availability, cost-effectiveness and technically up-to-date state of a technical facility. The technical facility may be installed not only in stationary entities, such as buildings, but also in mobile entities, such as ships or aircraft. This aim is of course particularly worthwhile in large buildings with very highly ramified technical facilities, for example in industrial buildings, local authority buildings or public institutions and on large ships.

For the initialization phase, it is advantageous to characterize the lighting components in accordance with the following criteria: the number of luminaires and lamps and also the number of lamps per luminaire, the respective type of any ballast used and the number of operating hours per year.

In order not to have to carry out the identification of the component parts of the technical facility manually in the computer system, it is advantageous to connect the component parts of the technical facility to the computer system via a suitable bus system. The identification of the component parts is then supported by the bus system. For lighting systems, the Digital Addressable Lighting Interface (DALI) bus system, which has become increasingly established recently, is an example of a system that is suitable for this. For further details on DALI, reference should be made to the document US-A 2003/036807.

For the calculation of the servicing intervals, in the simplest case an estimated operating period of the component parts of the technical facility is used, based for example on an assumed average operating period per day multiplied by the effective number of days since installation.

For a more precise calculation of the servicing intervals, it is advantageous to determine the actual operating periods of the component parts via a bus system, for example via the measured-value pickups of the building services management system, and use them as a basis for the calculation.

In any event, the average service lives, stored on the databank system, are also used in addition to the estimated or actual operating periods for the calculation of the servicing intervals for each component part, or various service-life models of the lighting technology (system service life, useful service life) are also used. The calculation of servicing plans takes place in accordance with the guidelines of EN 12464 and the servicing factors of the lighting components made available from the databank.

In an advantageous development of the method according to the invention, an additional analysis phase is provided, in which at least one of the following method steps is performed for the component parts of the technical facility:
recording of the respective energy consumption value of a component part of the facility, stored in the databank system, for example dependent on the ballast with which a lamp is operated, and storage in the computer system,
calculation of an economical assessment factor from at least some of the specific data of each component part and storage in the computer system,
determination of the frequency of identical or similar component parts and storage in the computer system,
determination of the costs for the component parts of the technical facility and/or energy costs.

In the case of the economical assessment factor, the costs for a type of lamp that are incurred by the user if he illuminates a predetermined space for a predetermined time with a predetermined luminous flux are calculated, for example.

Furthermore, it is advantageous if the prognosis phase comprises one or more of the following additional method steps:
calculation of the replacement requirement for each component part of the technical facility within a preselectable time horizon,
calculation of the time for which each component part will last, measured on the basis of the current stock,
calculation of the energy, procurement and servicing costs,
preparation of an order list for the replacement requirement.

In an advantageous development of the method according to the invention, an additional optimization phase is provided, which comprises one or more of the following method steps:
reduction of the variety of types of equivalent component parts of the technical facility,
substitution of existing component parts by technologically improved component parts which are updated from a databank, the databank being adjusted and updated online with the data of the manufacturer, in accordance with criteria which can be selected by the user,
optimization of the spare parts store.

Optionally, a “what if appraisal” is provided, in which the proposal of the expert system in the optimization phase is compared with the current situation. In a comparison, the investment requirement and the cost-effectiveness are calculated for both variants, and so are the saving and the amortization time for the optimization proposal.

In the event that the component parts are lamps and/or associated operational devices, a light control and/or constant-light control may be additionally provided in the lighting system to enhance its performance. The DALI bus system already mentioned is particularly well-suited in this connection also.

Finally, a development of the invention envisages calculating the characteristic economic data, in particular energy and servicing costs, of the facility as an absolute amount per period of time, for example year, and specifically per unit area, for example in square meters, by recursive summation over a selected area of the building and all the rooms in it in which the facility is installed, and preparing a report on this, for example the costs per room, story, building, unit of real estate, etc. The selection of the area concerned by the recursion takes place for example by selection in a hierarchical tree.

Also claimed is a computer program, which performs the method steps according to the invention during operation, and also a data carrier, on which the computer program is stored.

### BRIEF DESCRIPTION OF THE DRAWINGS

The invention is to be explained in more detail below on the basis of an exemplary embodiment. In the figures:

FIG. 1 shows a hierarchical breakdown of the parts of a building that are relevant with regard to the lighting system,

FIG. 2 shows a tabular overview of some data of the lamps installed in a room,

FIG. 3 shows the screen layout of the homepage of software in which the method according to the invention is implemented, and further pages can be called up,

FIG. 4 shows the screen layout of the “room” page,

FIG. 5 shows the screen layout of the “overview” page,

FIG. 6 shows the screen layout of the “luminaire” page,

FIG. 7 shows the screen layout of the “costs” page,

FIG. 8 shows the screen layout of the “servicing+prognosis” page,

FIG. 9 shows the screen layout of the “LampAnalyzer” page,

FIG. 10 shows the screen layout of the “individual luminaire” page,

FIG. 11 shows the screen layout of the “lamp search engine” module.

### BEST MODE FOR CARRYING OUT THE INVENTION

The exemplary embodiment relates to software for the maintenance of lighting systems. It is programmed in the “Java” language and therefore independent of the operating system of the computer used. Furthermore, it is distinguished inter alia by a modular construction, the individual modules also being able to operate on their own (modular principle).

In a first step (initialization phase), the stock of lamps and lamp ballasts, optionally also luminaires, of the lighting system is determined and documented. This may take place either manually by input in the computer system or ideally in an automated manner via the DALI interface, by which the electronic ballasts register themselves with the central server.

Only 5 characteristic values are necessary for characterizing the components of the lighting system:
1) number of luminaires,
2) the number of lamps per luminaire,
3) the lamp designation,
4) the type of ballast,
   a) no ballast,
   b) conventional ballast,
   c) electronic ballast,
   d) low-loss ballast
5) the operating time per year.

Other lamp-specific variables, such as for example:
the order designation,
the EAN code,
the service life,
the connected load,
the base,
the luminous flux,
the dimensions,
the shipping unit,
the purchase price,
a picture,
   are determined by access to a databank in which the lamp data are stored. Updating of the data may take place by means of an online data adjustment with the lamp manufacturer.

In the next step, an analysis (“LampAnalyzer” module) takes place, and possibly an assessment (“Ranking”), with regard to the energy consumption of the lamps, for example in accordance with Directive 98/11/EU and the German Energieverbrauchskennzeichnungsverordnung [German ordinance on energy consumption labeling]. In addition, a special assessment factor is calculated from various technical and economic criteria, such as product innovation, running costs, dimmability, light yield and color rendition of the lamp. Furthermore, the type diversification of the lighting system is recorded, i.e. the frequency of identical or similar types of lamp.

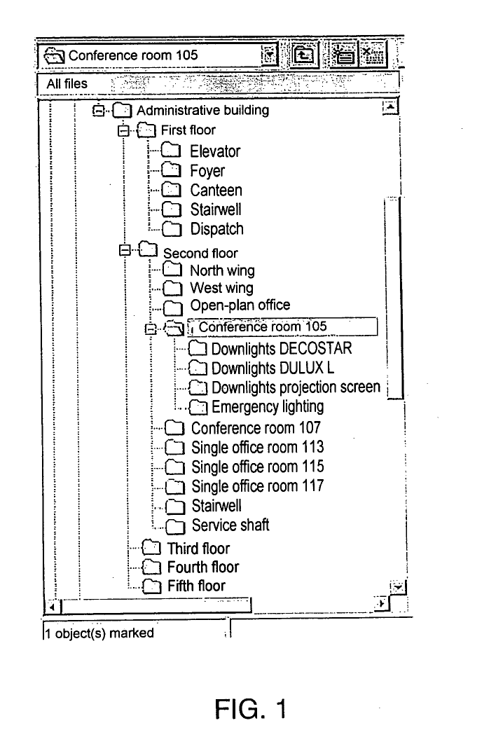

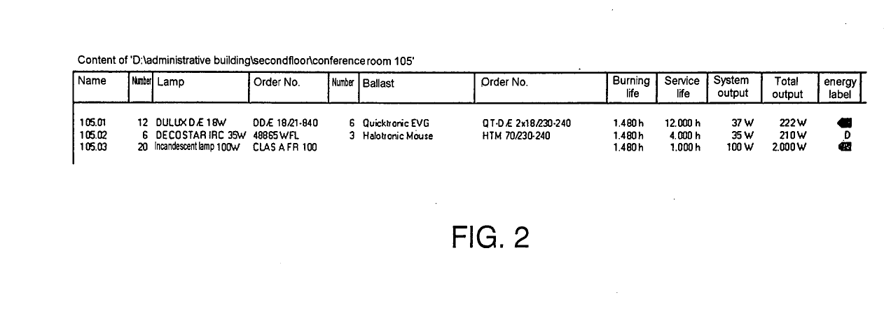

Shown in FIGS. 1 and 2 by way of example for an administrative building is the screen layout of the software in a kind of “expert mode”, as typically obtained after completion of the initialization and analysis phases.

FIG. 1 shows the hierarchical breakdown of the component parts of this building that are relevant with regard to the lighting system, for example the various stories with the rooms respectively located there, the elevator, the stairwell, the emergency lighting system, etc. Marked here by way of example is the conference room 105. Corresponding to this is the view shown in FIG. 2 in the form of an extract, in which the lamps installed in this room are listed in the form of a table, including important data such as for example their number, burning life, service life, energy label, etc.

In the prognosis phase which follows, servicing intervals after which the lamps can be expected to fail are determined. Serving as a basis for this are use profiles, based on the time period of daily, weekly, monthly or yearly operating hours of each lamp and also the product databank from which the average service life or other service-life models (system service life, useful service life) can be taken for example. Optionally, an early warning time is freely selectable, in order to be informed by the computer in good time before the forecast failure of the respective lamp.

Also advantageous in this connection is the additional “stockkeeping” module (StockOptimizer), which optimizes the replacement requirement needed for all types of lamp, i.e. not too many but not too few either, to be precise depending on the time horizon considered, i.e. for a freely selectable time period, for example 6 months, 1 year, etc. In this case it is possible to call up on the one hand how long the current stock will last, on the other hand the likely procurement and servicing costs. Furthermore, purchasing lists are prepared for various ordering channels, for example by e-mail, fax or online ordering (e-business), and an order form is transmitted to the lamp manufacturer on request.

In the optimization module (“LampOptimizer”), an expert system proposes a number of substitutes for each type of lamp and assesses them in accordance with various criteria, for example quality, performance, cost-effectiveness, it being possible for the user to prioritize these criteria. On request, optimization proposals for the existing equipment can be displayed, using savings and amortization as a basis for taking a decision to change over to higher-quality types of lamp. A further optimization criterion is a reduction in the variety of types, involving the advantages of easier stockkeeping, improved level of service and simplified product procurement, on the basis of greater numbers of units per type of lamp on possibly better terms.

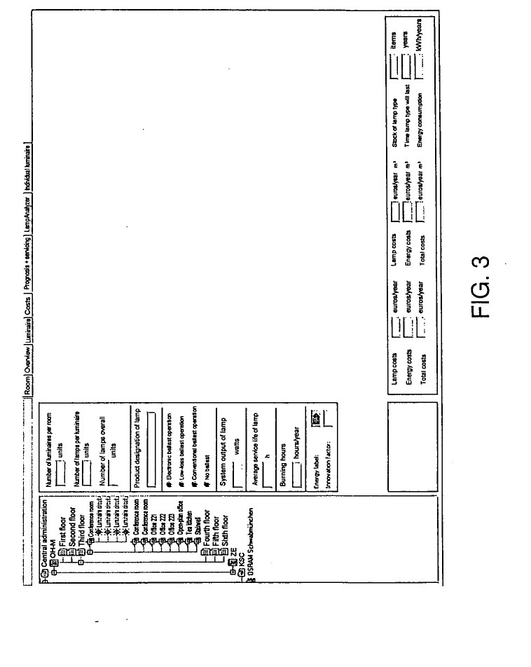

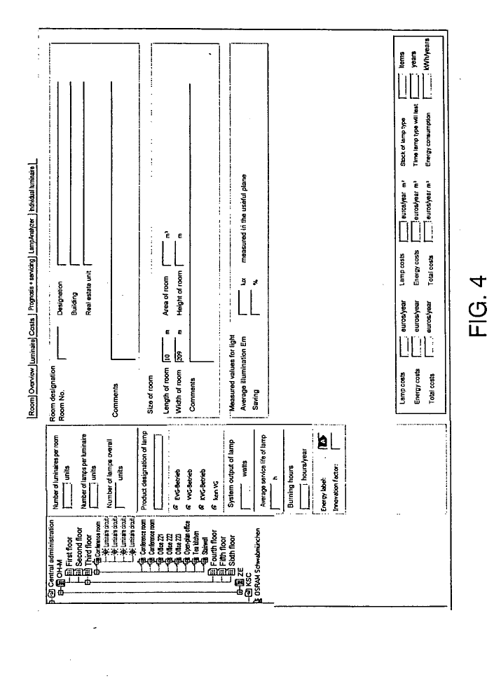

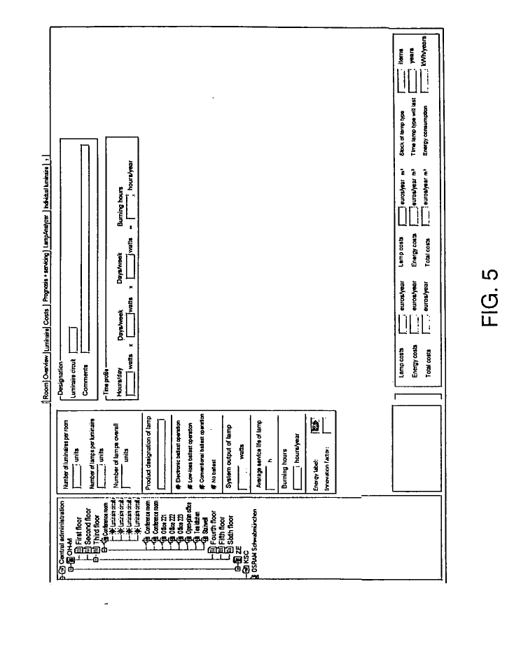

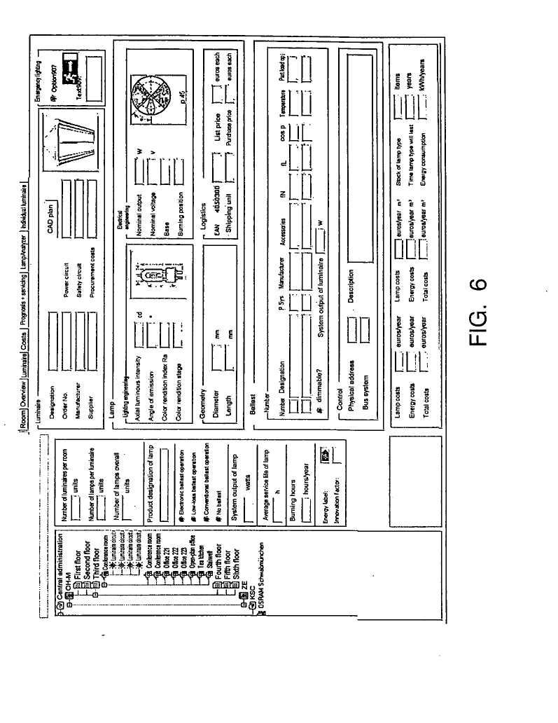

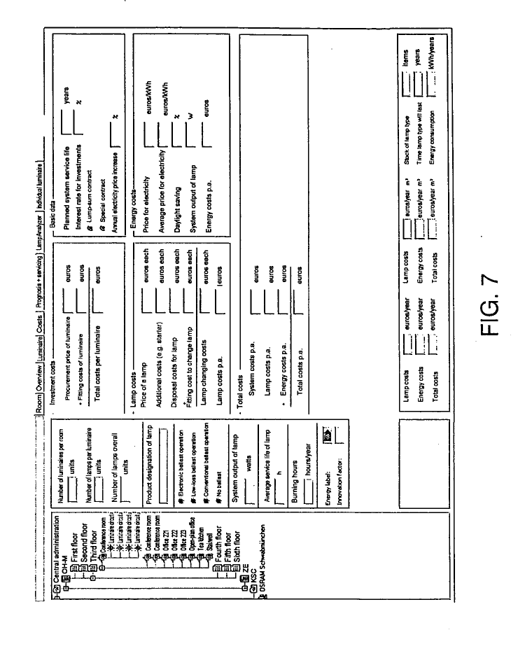

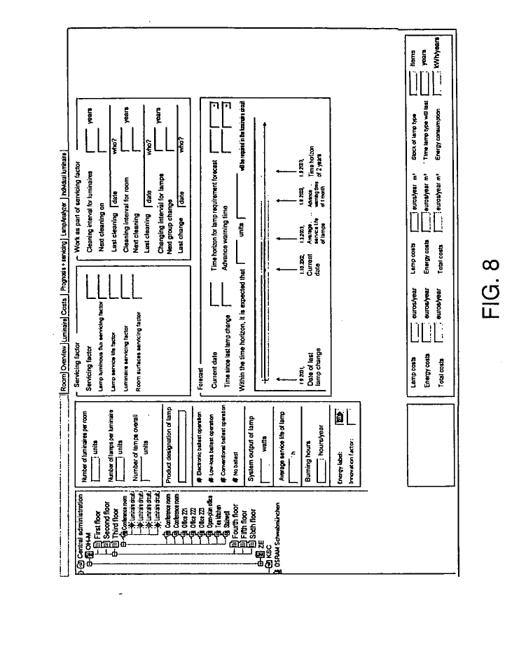

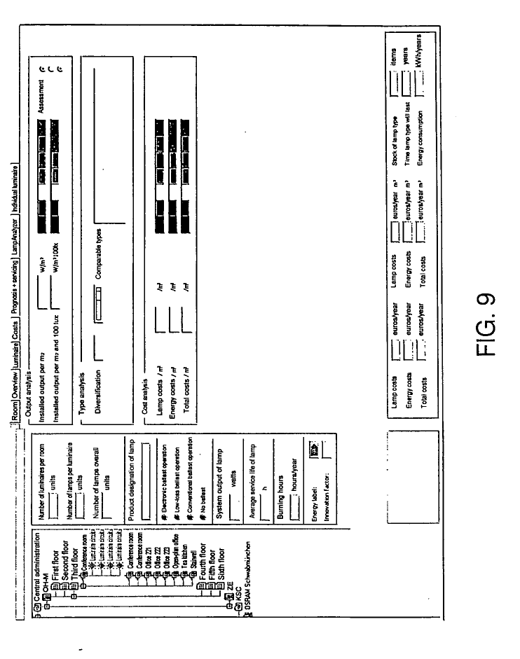

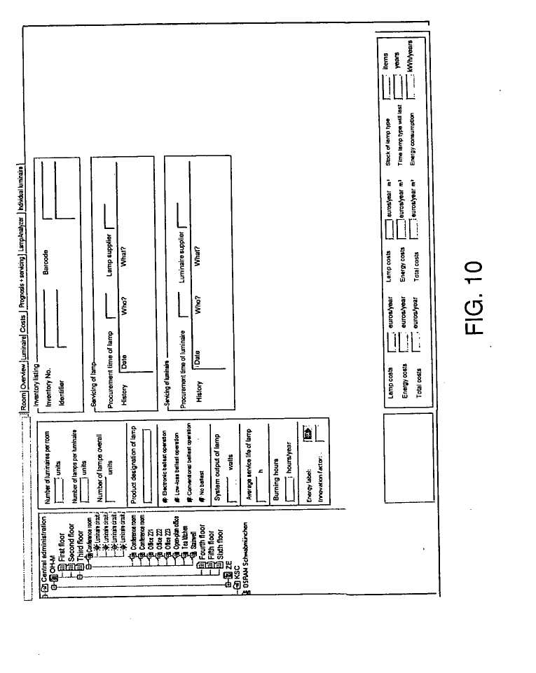

More graphically complex implementation of the software in comparison with the “expert mode” of FIGS. 1 and 2 is represented in FIGS. 3 to 10. FIG. 3 shows the screen layout of the homepage, from which it is possible to call up further pages, designated by “overview”, “room”, “luminaire”, “costs”, etc. These further pages are represented in FIGS. 4 to 10. The layout of the individual pages is designed here to allow even a user with little technical training to operate this software.

In order that the selection of the lamps is easy even for a layman to carry out, in a development an additional “lamp search engine” module is provided, which makes it possible for the correct types of lamp to be selected as follows:
1) selection of the product category, general purpose, halogen, fluorescent, compact fluorescent, high-pressure discharge, photographic optics, automotive or flat radiator lamp, and also light-emitting diodes (LED), by means of graphic symbols and descriptive text,
2) further selection criteria, such as for example the form of bulb, constructional form, base, output, color of the light, length, and further distinctive features of the lamp are restricted by graphic and text filters until the user is given such a reduced selection of types that easy selection is possible. The selection is displayed by pictures or diagrams.

In this way, a concise list of only a few types of lamp, with common features predetermined by filters, is taken from the extensive but confusing list of the overall selection of all available types of lamp.

Input of the order designation in plain text is likewise possible. If in this case parts of the order designation are input, the search engine displays the list of the types that come into consideration.

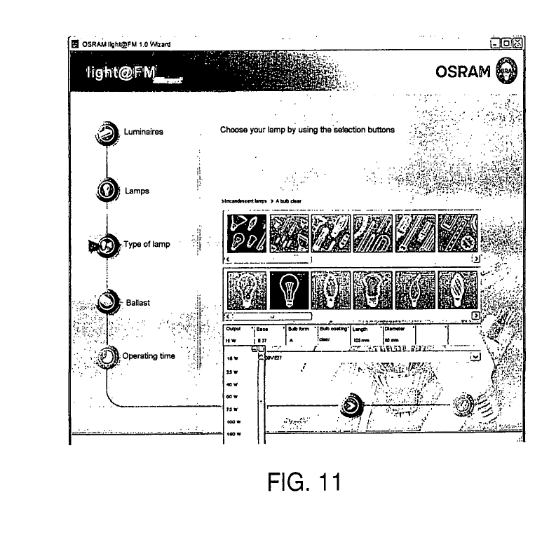

In FIG. 11, the screen layout of the lamp search engine module is represented by way of example.

The individual modules of the software, such as the LampAnalyzer, LampOptimizer or StockOptimizer and others, are represented by autonomous programs (Java applets). The data which can be fed into the system via a number of input channels (for example Excel, ASCII or XML) are processed by these modules. The results are passed on to another module or a report is generated and made available to a CAFM program already with the user or to the computer system of the lamp manufacturer, for example via an XML, Excel or ASCII interface.

Furthermore, remote servicing of the system via the Internet is also possible in principle.

1. A method for maintaining a technical facility, in particular a lighting system, with the aid of a computer system and the following method steps,
in an initialization phase:
identification of the component parts of the technical facility,
recording of specific data of the component parts with the aid of a databank system connected at least periodically to the computer system,
storage of the specific data assigned to the component parts in the computer system,
in a prognosis phase:
calculation of servicing intervals and preparation of servicing plans for the component parts of the technical facility on the basis of the specific data of these component parts.

2. The method as claimed in claim 1, the component parts of the technical facility being connected to the computer system via a bus system and the identification of the component parts taking place via the bus system.

3. The method as claimed in claim 2, the DALI bus system being used as the bus system.

4. The method as claimed in claim 1, the calculation of the servicing intervals being based on estimated operating periods of the component parts of the technical facility.

5. The method as claimed in claim 1, the calculation of the servicing intervals being based on actual operating periods of the component parts determined by the computer system via the bus system.

6. The method as claimed in claim 4, the calculation of the servicing intervals being based on the average service lives or other service life models stored for each component part in the databank system.

7. The method as claimed in claim 1, with an additional
analysis phase,
in which at least one of the following method steps is performed for the component parts of the technical facility:
recording of the respective energy consumption value, stored in the databank system, and storage in the computer system,
calculation of an assessment factor from at least some of the specific data and storage in the computer system,
determination of the frequency of identical or similar component parts and storage in the computer system,
determination of the costs for the component parts of the technical facility and/or energy costs.

8. The method as claimed in claim 1, the prognosis phase comprising one or more of the following additional method steps:
calculation of the replacement requirement for each component part of the technical facility within a preselectable time horizon,
calculation of the time for which each component part will last, measured on the basis of the current stock,
calculation of the procurement and servicing costs,
preparation of an order list for the replacement requirement.

9. The method as claimed in claim 8, with an additional
optimization phase,
which comprises one or more of the following method steps:
reduction of the variety of types of the component parts of the technical facility,
substitution of existing component parts by technologically improved component parts which are updated from a databank, the databank being adjusted and updated online with the data of the manufacturer, in accordance with criteria which can be selected by the user,
optimization of the spare parts store.

10. The method as claimed in claim 9, with an additional
“what if appraisal”,
which comprises the following method steps:
calculating
the investment requirement,
the cost-effectiveness, for the existing component parts and for the optimized component parts,
calculating
the saving,
the amortization time, for the optimized component parts.

11. The method as claimed in claim 1, the component parts being lamps and/or associated operational devices.

12. The method as claimed in claim 11, a light control and/or a constant-light control being additionally provided.

13. The method as claimed in claim 1, in which the characteristic economic data, in particular energy and servicing costs, of the facility are calculated as an absolute amount per period of time and per unit area recursively over all the areas of a building in which the facility is installed, and all the rooms located in it, and are reported.

14. A computer program, which performs the method steps as claimed in claim 1 during operation.

15. A data carrier, on which the computer program as claimed in claim 14 is stored.

16. The method as claimed in of claim 5, the calculation of the servicing intervals being based on the average service lives or other service life models stored for each component part in the databank system.

17. The method as claimed in claim 7, the prognosis phase comprising one or more of the following additional method steps:
calculation of the replacement requirement for each component part of the technical facility within a preselectable time horizon,
calculation of the time for which each component part will last, measured on the basis of the current stock,
calculation of the procurement and servicing costs,
preparation of an order list for the replacement requirement.
